(19) United States
(12) Patent Application Publication
(10) Pub. No.: US 2022/0346225 A1
(43) Pub. Date: Oct. 27, 2022

(54) SIMPLIFIED PEN CORE MODULE AND THE PREPARATION METHOD THEREOF

(71) Applicant: YingKeSong BiYe Research and Development Center Shenzhen CO.,LTD, Shenzhen (CN)

(72) Inventor: Hao Liu, HEYUAN (CN)

(21) Appl. No.: 17/241,514

(22) Filed: Apr. 27, 2021

(51) Int. Cl. H05K 1/02; H05K 3/46; H05K 1/11; G06F 3/0354

(52) U.S. Cl. CPC H05K 1/0298; H05K 1/028; H05K 3/4664; H05K 1/111; G06F 3/03545; H05K 2203/162; H05K 2203/04

(57) ABSTRACT

This invention discloses a simplified pen core module and the preparation method thereof. The pen core module is characterized in that it adopts PCB board as the main body of pen core, and the PCB board is covered with FPC boards that serve as pins; a hollow threaded seat is sleeved at the strip part of the PCB board, and is electrically connected with and fixed at the root step of the strip part; a hollow metal cylinder and a hollow cone part are sleeved in sequence at the relative position of the strip part of the PCB board and, through the hollow interior thereof, electrically connected with the bonding pad of the PCB board and fixed at the relative position; a heat resisting insulation ring is sleeved between every two of the threaded seat, metal cylinder and cone part.

### TECHNICAL FIELD

This invention relates to the technical field of electronic capacitance pen, especially a simplified pen core module and the preparation method thereof.

### BACKGROUND ART

As the mainstream input technology for touch panel, capacitive touch has been widely applied to any equipment that uses a touch screen such as mobile communication device and tablet computer. At present, the touch screen is available with either finger or capacitance pen for input operation. However, the core structure of existing special-purpose capacitance pen in the market is excessively complex, thus resulting in low production efficiency and high manufacturing cost; meanwhile, in existing technologies, the core structure typically entails the bonding and coordination of more than one component, and is likely to produce a variety of defects in industrial production, thus causing enormous waste of manpower and materials and making it unsuitable for mass production.

Existing technology CN210402293U disclose a simplified active capacitance pen module, which is characterized in that the pen core components (including receiving head, pen core cylinder, pen core holder, wire and spring) are wrapped with such structures as conical pen head, threaded part, plastic sleeve and pen head cap, and connected with a circuit board, making the resultant core structure extremely difficult to assembly with especially low yield rate;

Besides, existing technology KR1020160022369A discloses an electronic pen, which is characterized in that the pen core is installed in object 210 through circuit carrier 208, and writing pad 203 is connected with piezoelectric generator 204 under the support of piezoelectric engine 205 and digital control device 217, making the pen structure quite complex.

This invention discloses a capacitance pen, which is characterized by an integral pen core. The pen core is welded with a PCB board through annular components, thanks to which is can achieve all the pen core functions enabled by existing technologies with a greatly simplified structure, thus satisfying the needs of users for delicate and multifunctional writing or painting and other input operations on touch panel, while reducing the failure rate of capacitance pen and the cost of industrial assembly thereof.

### INVENTION CONTENTS

This invention aims to provide a simplified pen core module targeting the defects and deficiencies in existing technologies. The pen core module adopts PCB board as the main body of pen core in lieu of a large quantity of complex structural components. It also adopts the inner hole welding technology, which can greatly simplify procedures and reduce processing time and reject rate, while ensuring smooth, clean and intact appearance.

In order to achieve the purpose mentioned above, this invention provides the following technical proposal:

A simplified pen core module, which is characterized in that a PCB board and the annular components sleeved at the PCB board constitute the main body of pen core; the PCB board is provided with three layers of circuits, namely primary emitting circuit, secondary emitting circuit and grounding circuit; the back end of the PCB board is connected with pins, and the pins are electrically connected with the aforesaid three circuits on the PCB board.

Preferably, the PCB board is covered with FPC boards that serve as pins; the three layers of circuits are all electrically connected with the FRC boards and conducting to the pins corresponding to them.

Preferably, the annular components include a hollow cone part, a hollow metal cylinder and a hollow threaded seat, which are sleeved in sequence at the PCB board, with a heat resisting insulation ring being arranged between every two of them (all such insulation rings are sleeved at the PCB board); the insulation rings can, through separating the hollow cone part, metal cylinder and threaded seat, inhibit their mutual electrical effects to improve the writing accuracy of capacitance pen, and they are also used to determine the insulation and spacing distance of the aforesaid components, and fill in the gaps therebetween, thus beautifying the appearance of capacitance pen.

Preferably, the PCB board has a sleeving part, which is used to sleeve annular components and insulation rings; the back end of the sleeving part is connected with a step part, which forms a stop with the hollow threaded seat; an extension part is provided behind the step part, which is composed of EPC boards.

Preferably, the PCB board is provided with more than one bonding pad, which are respectively welded and electrically connected with the hollow interior of the cone part, metal cylinder and threaded seat; the metal cylinder is electrically connected with the secondary emitting circuit, and the threaded seat and the cone part are electrically connected with the grounding circuit.

Preferably, the end face of the PCB board's sleeving part far away from the step part is provided with a primary emitting end face, which is electrically connected with the primary emitting circuit; the hollow threaded seat is sleeved at the strip part of the PCB board, which is electrically connected with and fixed at the root step of the strip part, and is also electrically connected with the grounding circuit.

An assembly method for pen core module, which is characterized in that a PCB board and the annular components sleeved at the PCB board constitute the main body of pen core; the PCB board is provided with three layers of circuits, namely primary emitting circuit, secondary emitting circuit and grounding circuit; the back end of the PCB board is connected with pins, and the pins are electrically connected with the aforesaid three circuits on the PCB board; the bonding pads on the PCB board are all coated with solder paste; the annular components (namely the hollow cone part, metal cylinder and threaded seat) and the insulation rings installed therebetween are sleeved at the PCB board in sequence; the annular components are then filled with solder paste upon the completion of assembly thereof, followed by the heating of the pen core module by virtue of the heating component thereof, which melts the solder paste and consequently achieves the electric connection between the interior surfaces of the annular components with the bonding pads of the PCB board, and then the molten solder paste changes into solid tin when cooling down, making the hollow annular components fixed with the PCB board, thus completing the assembly of the pen core module; finally, the circuits of the pen core module are tested by virtue of the testing component thereof to ensure the qualification of assembly.

In conclusion, compared with existing technologies, this invention has the following beneficial effects:

(1) This invention is reasonable in design. It adopts PCB board as the main body of pen core and, through optimizing the structure of the PCB board adopted, enable it to be sleeved together with several hollow annular components, and be further connected with the primary emitting circuit, secondary emitting circuit and grounding circuit through such annular components, thus simplifying pen core structure by directly replacing a large quantity of complex structural components;

(2) The PCB board adopts a three-layer circuit structure. The design of multiple circuit layers can improve the strength of the PCB board as the main body of pen core, and the combination of this design mode and the layout of bonding pads can further increase the welding stability and strength between the PCB board and the hollow components, and avoid capacitance pen failures resulting from the collision or dropping thereof in the process of use; in addition, the inner hole welding technology is adopted in the process of assembly, which can greatly reduce manpower and material consumption, while ensuring a smooth, clean and intact appearance of pen core.

(3) FPC boards are set behind the PCB boards that serve as pins. The PCB board can be connected with the main control panel of capacitance pen through FPC, thus improving the performance of electrical connection thereof. To be specific, FPC can provide flexible connection, which can avoid failures due to the disconnection of electrical connection points under impact arising from the drop of capacitance pen, etc., thus further improving the crash resistance of capacitance pen;

(4) Upon the completion of assembly of the improved pen core module, the PCB board, main body of pen core, will be completely wrapped by the aforesaid annular components, which can prevent the circuits on the PCB board from being scratched, collided or otherwise damaged, thus further improving the stability of pen core components.

### DRAWINGS EXPLANATION

In order to more clearly illustrate the embodiments regarding this invention or technical proposals involved in existing technologies, a brief introduction of the drawings required in the embodiments or the description of existing technologies will be given below. It is obvious that the drawings described below are only limited to embodiments regarding this utility model, based on which ordinary technicians concerned may also obtain other drawings without making any creative effort.

FIG. 1 refers to the structure diagram of embodiments regarding this invention.

FIG. 2 refers to the circuit diagram of such embodiments.

FIG. 3 refers to the circuit bonding pad diagram of such embodiments.

Drawing markers: 1—PCB+FPC boards, 2—cone part, 3—insulation ring, 4—metal cylinder, 5—threaded seat, A1—secondary emitting bonding pad, A2—secondary emitting pin, B1—primary emitting end face, B2—primary emitting pin, C1—cone part grounding bonding pad, C2—threaded part grounding bonding pad, C3—grounding pin.

### SPECIFIC IMPLEMENTATION MODES

The technical proposal involved in this invention is further explained as follows in combination with relevant drawings and embodiments.

### Embodiment 1

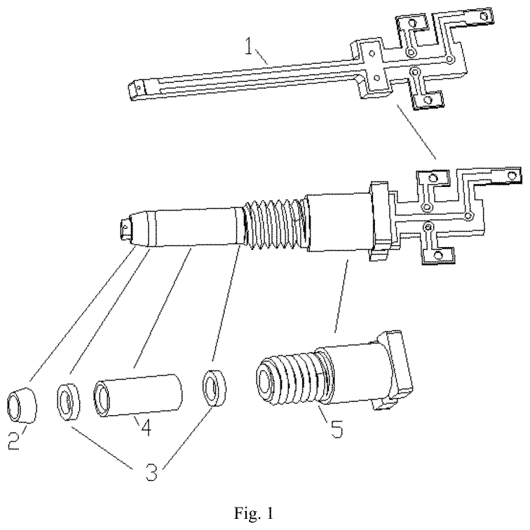

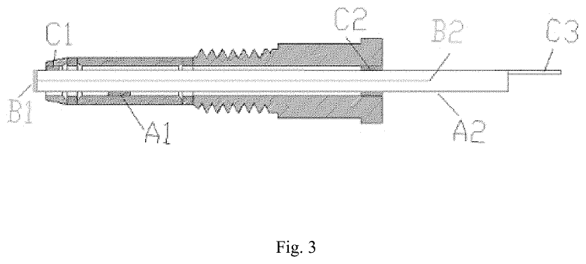

FIGS. 1-3 show a simplified pen core module, which is characterized in that a PCB board and the annular components sleeved at the PCB board constitute the main body of pen core; the PCB board is composed of sleeving part and step part, with annular components being sleeved at the sleeving part; the annular components include a hollow cone part (2), a hollow metal cylinder (4) and a hollow threaded seat (5); the step part forms a stop with the hollow threaded seat (5); the sleeving part is strip-shaped; the hollow cone part (2), metal cylinder (4) and threaded seat (5) are sleeved at the PCB board in sequence, with a heat resisting insulation ring (3) being arranged between every two of them (all such insulation rings are sleeved at the PCB board); an extension part is provided behind the step part, which is composed of EPC boards.

The PCB board (1) is also covered with FPC boards that server as pins. The PCB board (1) is provided with three layers of circuits, namely grounding circuit (C), primary emitting circuit (B) and secondary emitting circuit (A), which are all electrically connected with the FPC boards and conducting to the pins corresponding to them; a primary emitting end face (B1) is arranged at the end face of the strip part of the PCB board (1);

The PCB board is divided into three layers, namely the front layer (first layer), interlayer and back layer (third layer); a cone part grounding bonding pad (C1) is provided at a certain distance from the sleeving part on the front layer (first layer), and a threaded part grounding bonding pad (C2) is provided at the step part, which are in the same plane; a secondary emitting grounding pad (A1) and a threaded part grounding bonding pad (C2) are provided at the back layer (third layer); a secondary emitting grounding pad (A1) is provided at the middle position between a cone part grounding bonding pad (C1) and a threaded part grounding bonding pad (C2);

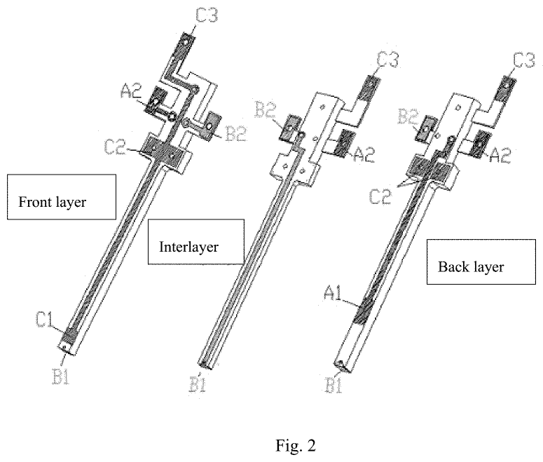

FIG. 2 shows that the grounding circuit (C) is composed of a cone part grounding bonding pad (C1), a threaded part grounding bonding pad (C2), a grounding pin (C3) and a conducting wire connecting them; the primary emitting circuit (B) is composed of a primary emitting end face (B1), a primary emitting pin (B2) and a conducting wire connecting them; the secondary emitting circuit (A) is composed of a secondary emitting end face (A1), a secondary emitting pin (A2) and a conducting wire connecting them; the three circuits are provided at different layers of the PCB board; the B1, B2, C2, C3 and A2 pins or end faces at different layers are corresponding to and overlapped with each other to facilitate connection;

A hollow threaded seat (5) is sleeved at the strip part of the PCB board (1), and is electrically connected with and fixed at the root step of the strip part; the hollow threaded seat (5) is also electrically connected with the grounding circuit (C);

A hollow metal cylinder (4) and a hollow cone part (2) are sleeved in sequence at the relative position of the strip part of the PCB board (1) and, through the hollow interior thereof, electrically connected with the bonding pad of the PCB board (1) and fixed at the relative position; the metal cylinder (4) is electrically connected with the secondary emitting circuit (A), and the cone part (2) is electrically connected with the grounding circuit (C).

A heat resisting insulation ring (3) is sleeved between every two of the threaded seat (5), metal cylinder (4) and cone part (2). The insulation rings are used to inhibit the mutual electrical effects between the three components to improve the writing accuracy of capacitance pen, and they are also used to determine the insulation and spacing distance of the aforesaid components, and fill in the gaps therebetween, thus beautifying the appearance of capacitance pen.

The end face of the PCB board's sleeving part far away from the step part is provided with a primary emitting end face (B1), which is electrically connected with the primary emitting circuit.

FIG. 2 shows that the three pins, A2/B2/C3, are composed of FPC boards, and electrically connected with the main panel of capacitance pen;

An assembly method for pen core module, which is characterized in that a PCB board and the annular components sleeved at the PCB board constitute the main body of pen core; the PCB board is provided with three layers of circuits, namely primary emitting circuit, secondary emitting circuit and grounding circuit; the PCB board is covered with FPC boards that serve as pins, and the aforesaid three circuits are all electrically connected with the FRC boards and conducting to the pins corresponding to them; the bonding pads on the PCB board are all coated with solder paste; the annular components (namely the hollow cone part, metal cylinder and threaded seat) and the insulation rings installed therebetween are sleeved at the PCB board in sequence; the annular components are then filled with solder paste upon the completion of assembly thereof, followed by the heating of the pen core module by virtue of the heating component thereof, which melts the solder paste and consequently achieves the electric connection between the interior surfaces of the annular components with the bonding pads of the PCB board, and then the molten solder paste changes into solid tin when cooling down, making the hollow annular components fixed with the PCB board, thus completing the assembly of the pen core module; finally, the circuits of the pen core module are tested by virtue of the testing component thereof to ensure the qualification of assembly.

The finished pen core module is installed in the capacitance pen kit, with the primary emitting end face (B1) thereof being electrically connected with the tip component of capacitance pen; the external thread of the hollow threaded seat (5) is connected with the internal thread of the capacitance pen kit, with the back end thereof being connected with the main control panel of capacitance pen.

### Embodiment 2

A simplified pen core module, which is characterized in that a PCB board and the annular components sleeved at the PCB board constitute the main body of pen core; the PCB board is composed of sleeving part and step part, with annular components being sleeved at the sleeving part; the annular components include a hollow cone part (2), a hollow metal cylinder (4) and a hollow threaded seat (5); the step part forms a stop with the hollow threaded seat (5); the sleeving part is strip-shaped; the hollow cone part (2), metal cylinder (4) and threaded seat (5) are sleeved at the PCB board in sequence, with a heat resisting insulation ring (3) being arranged between every two of them (all such insulation rings are sleeved at the PCB board); there are pins connected with the back end of the PCB board and electrically connected with the emitting and grounding circuits on the PCB board. In this embodiment, hard connection is adopted for the aforesaid connection with the back end of the PCB board; PCB board adopts metal wires such as copper wire and steel wire as pins; the metal wires adopted are electrically connected with the main control panel of capacitance pen to complete the assembly thereof;

The technical proposal adopting FPC boards as pins, although showing different performances in practice, is still a better choice than the technical proposal adopting metal wire for electrical connection, as the latter is featured by relatively firm but excessively rigid connection, which may bring about relatively hard handfeel in writing, and possibly result in the fracture or breaking of welding spots under external impact; besides, numerous manual welding spots can somehow increase operation difficulty in the process of processing and welding.

The technical proposal adopting FPC boards (flexible conducting wires) as pins can resolve the problem of rigid connection points, but accordingly entails more internal space to accommodate flexible conducting wires, and thus improve the impact resistance of capacitance pen.

In conclusion, this invention is reasonable in design. It adopts PCB board as the main body of pen core in lieu of a large quantity of complex structural components. It also adopts the inner hole welding technology, which can greatly reduce manpower and material consumption as well as reject rate, while ensuring smooth, clean and intact appearance.

The aforesaid welding technology can ensure the reliability and stability of electrical connection without leaving any welding trace on the outer surface, thus avoiding interfering with the combination of other parts due to external protrusion of welding spots, while ensuring the integrity and aesthetics of appearance.

The technical principles of this invention described above in combination with specific embodiments are only limited to the preferential implementation modes of this invention. However, the protection scope of this invention is by no means limited to the embodiments above, instead, it shall include all technical proposals under the concept of this invention, in other words, all other specific implementation modes regarding this utility model that can be thought of by technicians in this field without making any creative effort shall also fall into the protection scope of this invention.

I claim:

1. A simplified pen core module, which is characterized in that a PCB board and the annular components sleeved at the PCB board constitute the main body of pen core; the PCB board is provided with three layers of circuits, namely primary emitting circuit, secondary emitting circuit and grounding circuit; the back end of the PCB board is connected with pins, and the pins are electrically connected with the aforesaid three circuits on the PCB board.

2. The pen core module of claim 1 is characterized in that the pins are composed of FPC boards; the PCB board is covered with FPC boards that serve as pins; the three layers of circuits are all electrically connected with the FRC boards and conducting to the pins corresponding to them.

3. The pen core module of claim 1 is characterized in that the annular components include a hollow cone part, a hollow metal cylinder and a hollow threaded seat, which are sleeved in sequence at the PCB board, with a heat resisting insulation ring being arranged between every two of them (all such insulation rings are sleeved at the PCB board).

4. The pen core module of claim 1 is characterized in that the PCB board has a sleeving part, which is used to sleeve annular components and insulation rings; the back end of the sleeving part is connected with a step part, which forms a stop with the hollow threaded seat; an extension part is provided behind the step part, which is composed of EPC board.

5. The pen core module of claim 1 is characterized in that the PCB board is provided with more than one bonding pad, which are respectively welded and electrically connected with the hollow interior of the cone part, metal cylinder and threaded seat; the metal cylinder is electrically connected with the secondary emitting circuit, and the threaded seat and the cone part are electrically connected with the grounding circuit.

6. The pen core module of claim 1 is characterized in that the end face of the PCB board's sleeving part far away from the step part is provided with a primary emitting end face, which is electrically connected with the primary emitting circuit.

7. An assembly method for the pen core module of claim 1, which is characterized in that the bonding pads on the PCB board are all coated with solder paste; the annular components (namely the hollow cone part, metal cylinder and threaded seat) and the insulation rings installed therebetween are sleeved at the PCB board in sequence; the annular components are then filled with solder paste upon the completion of assembly thereof, followed by the heating of the pen core module by virtue of the heating component thereof, which melts the solder paste and consequently achieves the electric connection between the interior surfaces of the annular components with the bonding pads of the PCB board, and then the molten solder paste changes into solid tin when cooling down, making the hollow annular components fixed with the PCB board, thus completing the assembly of the pen core module; finally, the circuits of the pen core module are tested by virtue of the testing component thereof to ensure the qualification of assembly.
